(19) United States
(12) Patent Application Publication
(10) Pub. No.: US 2014/0291613 A1
(43) Pub. Date: Oct. 2, 2014

(54) MULTIPLE QUANTUM WELL STRUCTURE

(71) Applicants: Ching-Liang Lin, Tainan City (TW); Shen-Jie Wang, Tainan City (TW); Yen-Lin Lai, Tainan City (TW)

(72) Inventors: Ching-Liang Lin, Tainan City (TW); Shen-Jie Wang, Tainan City (TW); Yen-Lin Lai, Tainan City (TW)

(73) Assignee: Genesis Photonics Inc., Tainan (TW)

(21) Appl. No.: 13/851,953

(22) Filed: Mar. 27, 2013

(51) Int. Cl. H01L 29/15; H01L 29/205; H01L 29/06

(52) U.S. Cl. CPC H01L 29/151; H01L 29/0657; H01L 29/205
USPC 257/14

(57) ABSTRACT

A multiple quantum well structure including a plurality of well-barrier pairs arranged along a direction is provided. Each of the well-barrier pairs includes a barrier layer and a well layer adjacent to the barrier layer. The barrier layers and the well layers of the well-barrier pairs are disposed alternately. A ratio of a thickness of the well layer in the direction to a thickness of the barrier layer in the direction in each well-barrier pair is a well-barrier thickness ratio, and the well-barrier thickness ratios of a part of the well-barrier pairs gradually increase along the direction.

### BACKGROUND OF THE INVENTION

1. Field of the Invention

The invention relates to a quantum well structure, and more particularly, to a multiple quantum well structure.

2. Description of Related Art

When material dimensions are reduced to nanometer scale, not only the dimensions are considerably miniaturized, but also some quantum effects such as confinement effects, surface and interface effects, and tunneling effects become particularly apparent. These characteristics may be applied to electronic component development, biochip fabrication, sensitivity enhancement of medical instruments, and so on.

More specifically, due to particle and wave nature of electrons, in a nanomaterial, a length of an electron wave function is close to a feature size of a quantum structure, and the wave nature of electrons is sufficiently shown. Therefore, when a material is reduced to nanometer scale in a direction, the quantum confinement effect will appear in the direction. At this moment, the electrons are confined to move freely in a two-dimensional space constituted by the other two dimensions, and such system is called a quantum well. The quantum well utilizes a semiconductor layer having a higher band gap as a barrier layer and a semiconductor layer having a lower band gap as a well layer. In the quantum well, which is a well-like band structure formed by the well layer clamped by the barrier layers from two sides, carriers are easily confined, thus enhancing light emission efficiency.

During fabrication of the quantum well, a heterostructure is usually grown, for example, gallium nitride (GaN) and indium gallium nitride (InGaN) multiple quantum well structures are grown. When lattices of two grown heterostructure materials do not match each other, stress will accumulate in the structure. As growing thickness increases, the accumulated stress increases. When the stress exceeds a threshold value, the material layers cannot bear the stress any more and the stress has to be released in other ways. Accordingly, epitaxial defects are usually caused, leading to damage to the multiple quantum well structure, and further decreasing the light emission efficiency.

### SUMMARY OF THE INVENTION

The invention provides a multiple quantum well structure having low density epitaxially formed defects and good structural properties.

An embodiment of the invention provides a multiple quantum well structure. The multiple quantum well structure includes a plurality of well-barrier pairs arranged along a direction. Each well-barrier pair includes a barrier layer and a well layer adjacent to the barrier layer. The barrier layers and the well layers of the well-barrier pairs are disposed alternately. A ratio of a thickness of the well layer in the direction to a thickness of the barrier layer in the direction in each well-barrier pair is a well-barrier thickness ratio, and the well-barrier thickness ratios of a part of the well-barrier pairs gradually increase along the direction.

Another embodiment of the invention provides a multiple quantum well structure. The multiple quantum well structure includes a plurality of well-barrier pairs arranged along a direction. Each well-barrier pair includes a barrier layer and a well layer adjacent to the barrier layer. The barrier layers and the well layers of the well-barrier pairs are disposed alternately. A ratio of a thickness of the well layer in the direction to a thickness of the barrier layer in the direction in each well-barrier pair is a well-barrier thickness ratio. The well-barrier thickness ratios of at least a part of the well-barrier pairs gradually increase along the direction. The thicknesses of the barrier layers of the well-barrier pairs in the direction gradually decrease along the direction, while the thicknesses of the well layers of the well-barrier pairs in the direction gradually increase along the direction.

Still another embodiment of the invention provides a multiple quantum well structure. The multiple quantum well structure includes a plurality of sets of well-barrier pairs arranged along a direction. Each set of well-barrier pairs includes a plurality of adjacent stacked well-barrier pairs, and each well-barrier pair includes a barrier layer and a well layer adjacent to the barrier layer. The barrier layers and the well layers of the well-barrier pairs of the plurality of sets of well-barrier pairs are disposed alternately. A ratio of a total thickness of the well layers of the well-barrier pairs in the direction to a total thickness of the barrier layers of the well-barrier pairs in the direction in each set of well-barrier pairs is a total well-barrier thickness ratio, and the total well-barrier thickness ratios of at least a part of the well-barrier pairs gradually increase along the direction.

Based on the above, in the multiple quantum well structure according to an embodiment of the invention, the well-barrier thickness ratios of a part of the well-barrier pairs gradually increase along the arrangement direction. Accordingly, stress caused by lattice mismatch between the barrier layer and the well layer is effectively reduced, so as to reduce the chance of V-shaped defects being formed in the multiple quantum well structure, and further to effectively enhance the quality of the multiple quantum well structure. In the multiple quantum well structure according to another embodiment of the invention, at least a part of the well-barrier thickness ratios gradually increase along the arrangement direction. The thicknesses of the barrier layers and the well layers in the well-barrier pairs are graded, so as to effectively reduce the stress caused by lattice mismatch between the barrier layer and the well layer. Accordingly, the chance of the V-shaped defects being formed in the multiple quantum well structure is reduced, and further, the quality of the multiple quantum well structure is effectively enhanced. In the multiple quantum well structure according to still another embodiment of the invention, the total well-barrier thickness ratios of at least a part of the plurality of sets of well-barrier pairs gradually increase along the arrangement direction, so as to effectively reduce the stress caused by lattice mismatch between the barrier layer and the well layer. Accordingly, the chance of the V-shaped defects being formed in the multiple quantum well structure is reduced, and further, the quality of the multiple quantum well structure is effectively enhanced.

To make the aforementioned features and advantages of the invention more comprehensible, embodiments accompanied with figures are described in detail below.

### BRIEF DESCRIPTION OF THE DRAWINGS

FIG. 1A is a schematic view of a multiple quantum well structure according to an embodiment of the invention.

FIG. 1B is a band diagram corresponding to the multiple quantum well structure in FIG. 1A.

FIG. 2A is a schematic view of a multiple quantum well structure according to another embodiment of the invention.

FIG. 2B is a band diagram corresponding to the multiple quantum well structure in FIG. 2A.

FIG. 3A is a schematic diagram of a multiple quantum well structure according to still another embodiment of the invention.

FIG. 3B is a band diagram corresponding to the multiple quantum well structure in FIG. 3A.

FIG. 4A is a schematic view of a light emitting device according to an embodiment of the invention.

FIG. 4B is a schematic partial view of the light emitting layer in FIG. 4A.

FIG. 5 is a schematic view of a light emitting device according to another embodiment of the invention.

### DESCRIPTION OF EMBODIMENTS

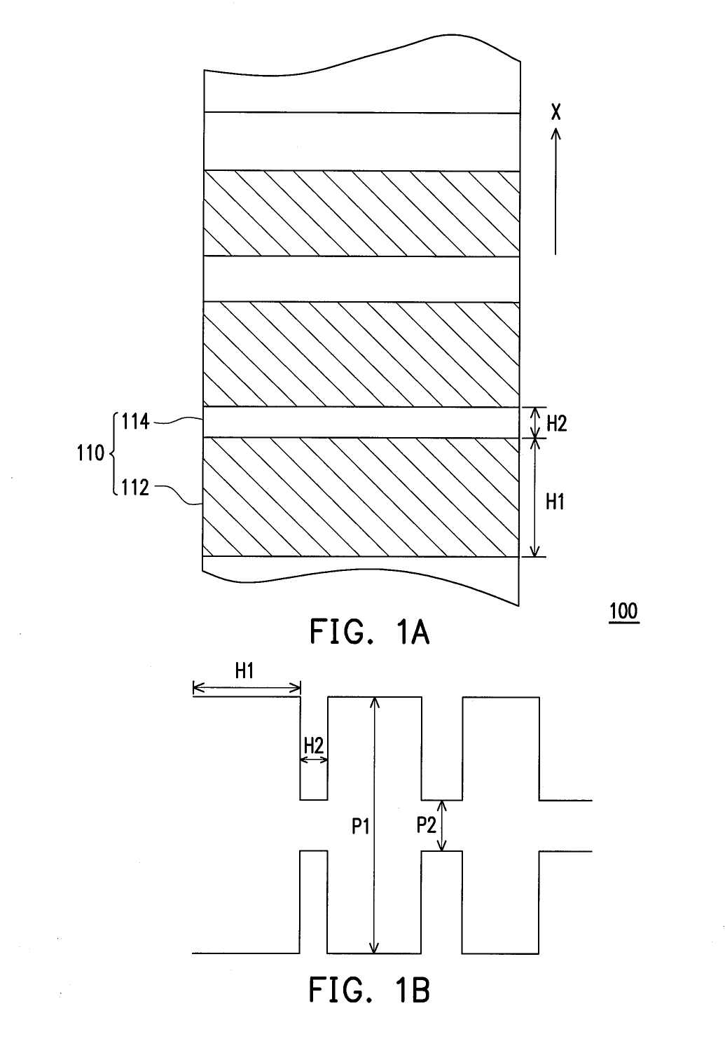

FIG. 1A is a schematic view of a multiple quantum well structure according to an embodiment of the invention. FIG. 1B is a band diagram corresponding to the multiple quantum well structure in FIG. 1A. Referring to FIG. 1A, a multiple quantum well structure 100 of the present embodiment includes a plurality of well-barrier pairs 110 arranged along a direction x. Each well-barrier pair 110 includes a barrier layer 112 and a well layer 114 adjacent to the barrier layer 112. The barrier layers 112 and the well layers 114 of the well-barrier pairs 110 are disposed alternately. A ratio of a thickness of the well layer 114 in the direction x to a thickness of the barrier layer 112 in the direction x in each well-barrier pair 110 is a well-barrier thickness ratio, and the well-barrier thickness ratios of a part of the well-barrier pairs 110 gradually increase along the direction x.

Referring to FIG. 1A, three well-barrier pairs 110 among the plurality of well-barrier pairs 110 are schematically illustrated in FIG. 1A. In the present embodiment, the number of the well-barrier pairs 110 in the multiple quantum well structure 100 is adjustable depending on the designer's needs. For example, the number of the well-barrier pairs 110 is in a range of 5 pairs to 25 pairs. The well-barrier pairs 110 are arranged along a direction, i.e. such as along the direction x in FIG. 1A. Moreover, a plurality of the barrier layers 112 and a plurality of the well layers 114 are disposed alternately. The alternate disposition of the barrier layers 112 and the well layers 114 results in a band structure formed by alternately disposing potential barriers P1 and potential wells P2. Referring to FIG. 1B, the potential barrier P1 having a larger band gap is contributed by the barrier layer 112 in FIG. 1A, and the potential well P2 having a smaller band gap is contributed by the well layer 114 in FIG. 1A.

In addition, the barrier layer 112 and the well layer 114 in each well-barrier pair 110 respectively have thicknesses H1 and H2 in the direction x, and the value of H2/H1 defines a well-barrier thickness ratio. In the present embodiment, the well-barrier thickness ratios (H2/H1) of a part of the well-barrier pairs 110 gradually increase along the direction x. In detail, in the three well-barrier pairs 110 among a part of the plurality of well-barrier pairs 110 as shown in FIG. 1A, the relative sizes of the well-barrier thickness ratios (H2/H1) of the three well-barrier pairs 110 are, for example, any two of the three well-barrier thickness ratios (H2/H1) increase along the direction x, or the three well-barrier thickness ratios (H2/H1) increase successively along the direction x.

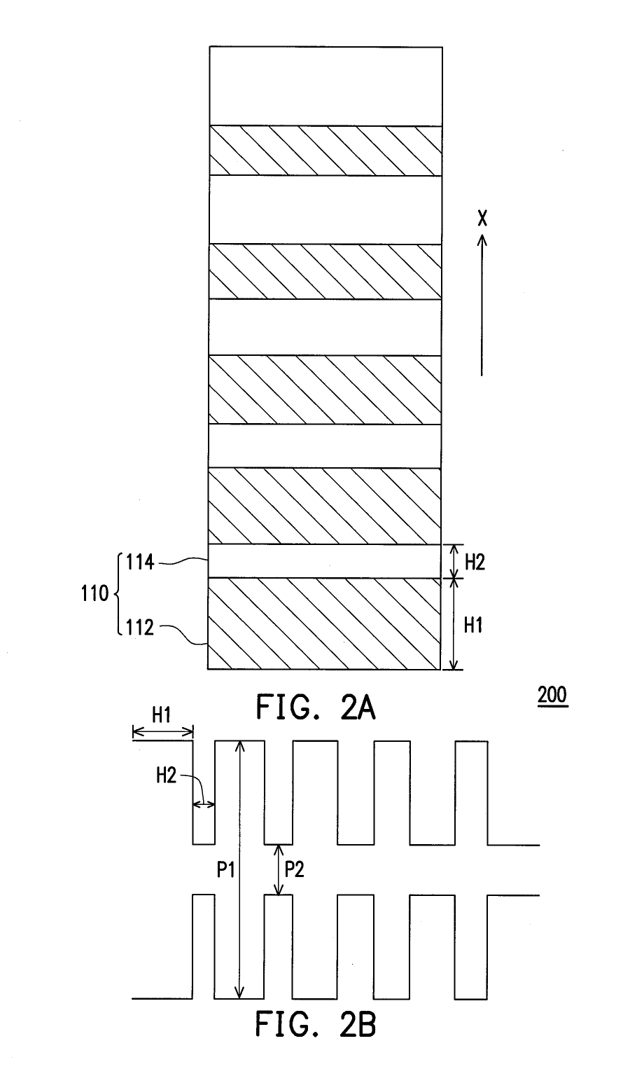

FIG. 2A is a schematic view of a multiple quantum well structure according to another embodiment of the invention. FIG. 2B is a band diagram corresponding to the multiple quantum well structure in FIG. 2A. Referring to FIG. 2A, a complete multiple quantum well structure 200 is illustrated in FIG. 2A. The multiple quantum well structure 200 of the present embodiment includes five well-barrier pairs 110. The multiple quantum well structure 200 in FIG. 2A is similar to the multiple quantum well structure 100 in FIG. 1A. However, the two multiple quantum well structures are different mainly in that in the multiple quantum well structure 100 in FIG. 1A, the well-barrier thickness ratios (H2/H1) of a part of the well-barrier pairs 110 gradually increase along the direction x, while in the multiple quantum well structure 200 in FIG. 2A, the well-barrier thickness ratios (H2/H1) of at least a part of the well-barrier pairs 110 gradually increase along the direction x. In other words, in the multiple quantum well structure 200, the well-barrier thickness ratios of a part of or all of the well-barrier pairs 110 gradually increase.

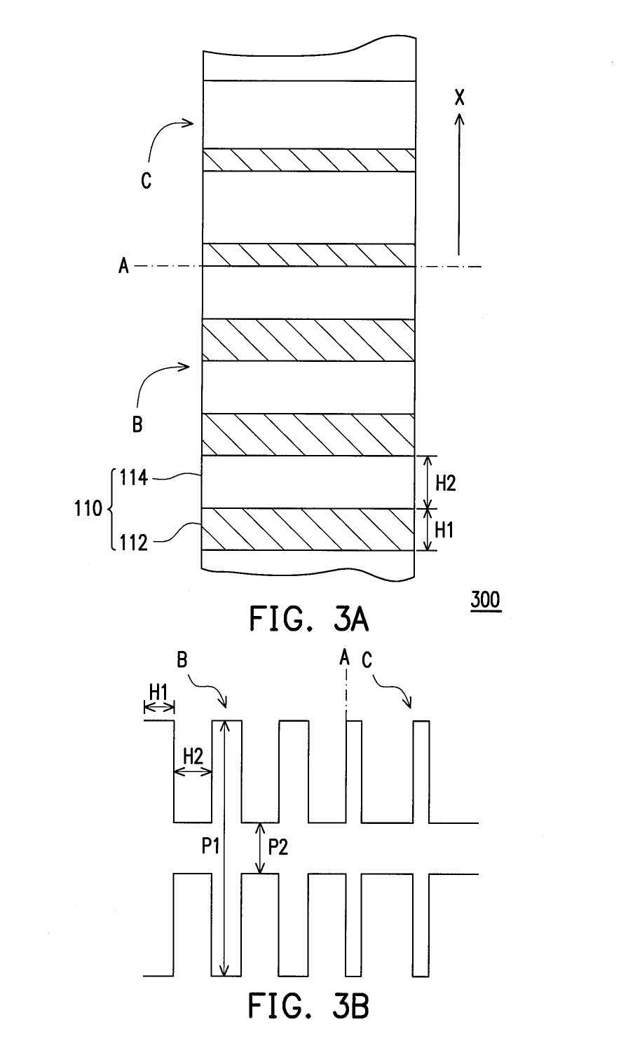

FIG. 3A is a schematic diagram of a multiple quantum well structure according to still another embodiment of the invention. FIG. 3B is a band diagram corresponding to the multiple quantum well structure in FIG. 3A. A multiple quantum well structure 300 in FIG. 3A is similar to the multiple quantum well structure 100 in FIG. 1A. However, the two multiple quantum well structures are different mainly in that the multiple quantum well structure 300 includes a plurality of sets B, C of well-barrier pairs arranged along the direction x. Each of the sets B, C of well-barrier pairs includes a plurality of adjacent stacked well-barrier pairs 110. In addition, a ratio of a total thickness of the well layers of the well-barrier pairs in the direction x to a total thickness of the barrier layers of the well-barrier pairs in the direction x in each of the sets B, C of well-barrier pairs is a total well-barrier thickness ratio, and the total well-barrier thickness ratios of at least a part of the plurality of sets B, C of well-barrier pairs gradually increase along the direction x.

Referring to FIG. 3A, two sets B, C among the plurality of sets of well-barrier pairs are schematically illustrated in FIG. 3A. In FIG. 3A, the two sets B, C of well-barrier pairs are separated by the dashed dotted line A, wherein the set B has three well-barrier pairs 110 and the set C has two well-barrier pairs 110. Accordingly, the set B has three barrier layers 112 each having the thickness H1 in the direction x and three well barriers 114 each having the thickness H2 in the direction x, and the set C has two barrier layers 112 each having the thickness H1 in the direction x and two well barriers 114 each having the thickness H2 in the direction x. Therefore, the set B has a summed thickness H1′ of the barrier layers 112 and a summed thickness H2′ of the well layers 114, such that a total well-barrier thickness ratio (H2′/H1′) is obtained. Similarly, the set C also has a total well-barrier thickness ratio (H2′/H1′). In the present embodiment, the total well-barrier thickness ratio (H2′/H1′) gradually increases along the direction x. Thus the total well-barrier thickness ratio (H2′/H1′) of the set C is greater than the total well-barrier thickness ratio (H2′/H1′) of the set B. However, in another embodiment, the total well-barrier thickness ratios (H2′/H1′) of the sets B and C may be the same, and the total well-barrier thickness ratio (H2′/H1′) of another set of well-barrier pairs located at a side of the set C opposite to the set B (such as the another set of well-barrier pairs above the set C in FIG. 3A) is greater, or the total well-barrier thickness ratio (H2′/H1′) of another set of well-barrier pairs located at a side of the set B opposite to the set C (such as the another set of well-barrier pairs beneath the set B in FIG. 3A) is smaller.

Referring to FIG. 1A to FIG. 3A, in the three embodiments, the well-barrier thickness ratios (H2/H1) of a part of the well-barrier pairs 110 gradually increase along the direction x, the thickness H1 of the barrier layer 112 of the well-barrier pair 110 in the direction x gradually decreases, and the thickness H2 of the well layer 114 of the well-barrier pair 110 in the direction x gradually increases. In other words, the thickness H2 of the well layer 114 gradually increases along the direction x, and meanwhile, the thickness H1 of the barrier layer 112 in the direction x gradually decreases, leading to a gradual increase in the well-barrier thickness ratio (H2/H1).

In the embodiments of FIG. 1A to FIG. 3A, the value of the well-barrier thickness ratio (H2/H1) of the well-barrier pair 110 is greater than or equal to 0.25 and is smaller than or equal to 2. In addition, in the embodiments of FIG. 1A to FIG. 3A, the gradual increase in the well-barrier thickness ratio (H2/H1) or in the total well-barrier thickness ratio (H2′/H1′) in the multiple quantum well structures 100, 200 and 300 may appear at least twice. For example, referring to FIG. 1A, at least three well-barrier pairs 110 are found in the multiple quantum well structure 100, and the well-barrier thickness ratios (H2/H1) of the three well-barrier pairs 110 gradually increase, in sequence, along the direction x. This means that the three well-barrier thickness ratios (H2/H1) are different and become successively greater along the direction x.

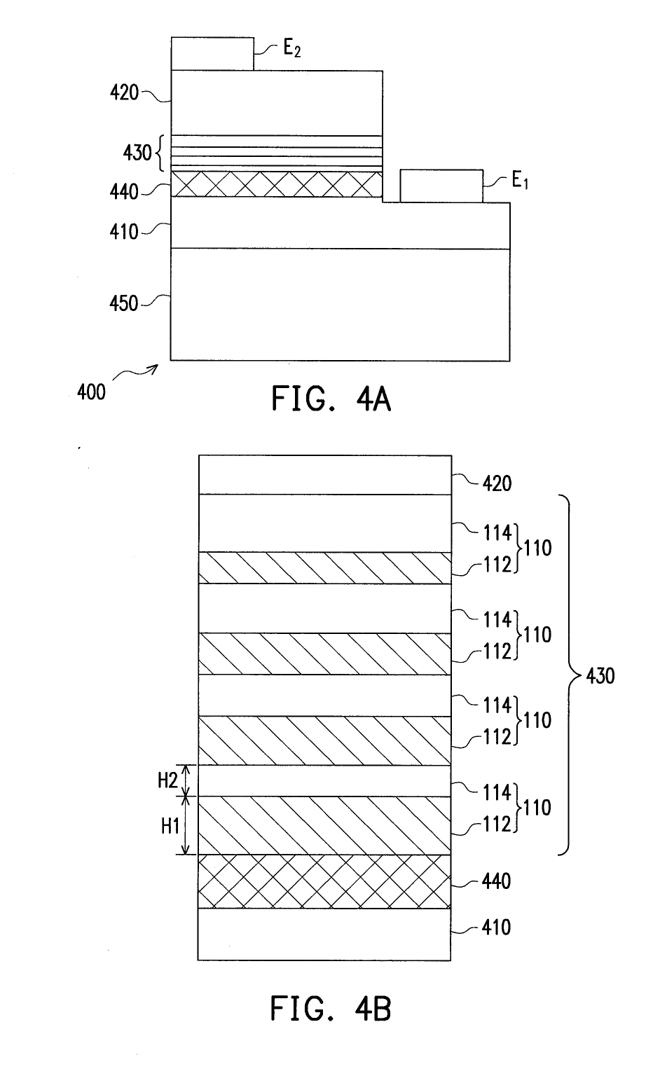

FIG. 4A is a schematic view of a light emitting device according to an embodiment of the invention, and FIG. 4B is a schematic partial view of the light emitting layer in FIG. 4A. Referring to FIG. 4A and FIG. 4B, a light emitting device 400 of the present embodiment is a horizontal-type light emitting device. The light emitting device 400 includes a substrate 450, a first type doped semiconductor layer 410, a light emitting layer 430, a second type doped semiconductor layer 420, a first electrode E1 and a second electrode E2. The first electrode E1 and the second electrode E2 are disposed facing the same side. The light emitting layer 430 is disposed on the first type doped semiconductor layer 410 and the second type doped semiconductor layer 420 is disposed on the light emitting layer 430, which means that the light emitting layer 430 is located between the first type doped semiconductor layer 410 and the second type doped semiconductor layer 420. Specifically, the first type doped semiconductor layer 410 is, for example, an n-type semiconductor layer, and the second type doped semiconductor layer 420 is, for example, a p-type semiconductor layer. The n-type semiconductor layer and the p-type semiconductor layer may be formed of at least one of GaN, AlGaN, InGaN and AlInGaN by doping group II elements or doping group IV elements. The present embodiment is described using GaN as an example. However, in other embodiments, the first type doped semiconductor layer 410 may be a p-type semiconductor layer and the second type doped semiconductor layer 420 may be an n-type semiconductor layer.

Still referring to FIG. 4A and FIG. 4B, in the light emitting device 400, the light emitting layer 430 employs the multiple quantum well structures 100, 200 and 300 as described in the embodiments of FIG. 1A to FIG. 3A. That is, the first type doped semiconductor layer 410 (such as an n-type semiconductor layer) and the second type doped semiconductor layer 420 (such as a p-type semiconductor layer) are respectively disposed at two opposite sides of the plurality of well-barrier pairs 110 in FIG. 4B. Moreover, the well-barrier thickness ratios (H2/H1) of a part of the well-barrier pairs 110 gradually increase from a side close to the first type doped semiconductor layer 410 (such as an n-type semiconductor layer) to a side close to the second type doped semiconductor layer 420 (such as a p-type semiconductor layer). Meanwhile, the thicknesses H1 of the barrier layers 112 of a part of the well-barrier pairs 110 gradually decrease from the side close to the first type doped semiconductor layer 410 (such as an n-type semiconductor layer) to the side close to the second type doped semiconductor layer 420 (such as a p-type semiconductor layer). The thicknesses H2 of the well layers 114 of a part of the well-barrier pairs 110 gradually increase from the side close to the first type doped semiconductor layer 410 (such as an n-type semiconductor layer) to the side close to the second type doped semiconductor layer 420 (such as a p-type semiconductor layer).

Referring to FIG. 4B, in the present embodiment, the barrier layers 112 in the plurality of well-barrier pairs 110 are, for example, GaN layers, and the well layers 114 are, for example, InGaN layers. Specifically, impurity in the GaN layer is less than 10%, and indium content in the InGaN layer is greater than 15%. Accordingly, the band gap is adjustable to enable the light emitting device 400 to emit light of a blue light band. In addition, in the present embodiment, the barrier layers 112 may also be AlGaN layers and the well layers 114 may be InAlGaN layers.

The light emitting layer 430 in the present embodiment employs the multiple quantum well structures 100, 200 and 300 as described in the embodiments of FIG. 1A to FIG. 3A. Specifically, the light emitting layer 430, for example, employs the multiple quantum well structure 300 of the embodiment of FIG. 3A, wherein the total well-barrier thickness ratios of a part of the plurality of sets of well-barrier pairs (such as B, C in FIG. 3A) gradually increase along the direction x. Thus in the case where the light emitting layer 430 employs the multiple quantum well structure 300, the thickness H1 of the barrier layer 112 closest to the first type doped semiconductor layer 410 (such as an n-type semiconductor layer) is greater than the other thicknesses H1 of the other barrier layers 112. Accordingly, the plurality of well-barrier pairs 110 has better structural properties. In the example where the barrier layer 112 and the well layer 114 are respectively a GaN layer and an InGaN layer, stress is caused in the quantum well due to mismatch of lattice constants between GaN and InGaN. When a thickness of the epitaxy of InGaN exceeds a threshold value, a total free energy and the accumulated stress tend to be reduced by means of dislocation, which extends to a surface to form a V-shaped crack defect. Therefore, in the present embodiment, the thinner well layer 114 being epitaxially formed on the thicker barrier layer 112 in the beginning has better crystallinity, so as to decrease the V-shaped defects caused by dislocation, and further, to improve recombination of electrons and holes and to enhance light emission efficiency.

In addition, the light emitting layer 430, for example, employs the multiple quantum well structure 100 of the embodiment of FIG. 1A, wherein the well-barrier thickness ratios of a part of the well-barrier pairs 110 gradually increase along the direction x. Thus in the case where the light emitting layer 430 employs the multiple quantum well structure 100, the thickness H2 of the well layer 114 of the well-barrier pair 110 closest to the second type doped semiconductor layer 420 (such as a p-type semiconductor layer) is greater than the other thicknesses H2 of the other well layers 114. Accordingly, there is better recombination of the electrons and holes. In detail, due to different equivalent masses between the electron and holes, the electrons and holes mostly recombine in the well layer 114 close to the second type doped semiconductor layer 420 (such as a p-type semiconductor layer). In the multiple quantum well structure 100 according to the embodiment of FIG. 1A, the thickness H2 of the well layer 114 close to the second type doped semiconductor layer 420 (such as a p-type semiconductor layer) is thicker, and thus more electrons are confined in the well. In other words, when the light emitting device 400 is driven, the well layer 114 closest to the second type doped semiconductor layer 420 (such as a p-type semiconductor layer) is capable of being loaded with more carriers, thus enhancing the whole light emission efficiency of the light emitting device 400.

It is also worth noting that the light emitting layer 430, for example, employs the multiple quantum well structure 200 of the embodiment of FIG. 2A, wherein the well-barrier thickness ratios of at least a part of the well-barrier pairs 110 gradually increase along the direction x, the thickness H1 of the barrier layer 112 gradually decreases along the direction x, and the thickness H2 of the well barrier 114 gradually increases along the direction x. Thus in the case where the light emitting layer 430 employs the multiple quantum well structure 200, the thickness H1 of the barrier layer 112 gradually decreases toward a side close to the second type doped semiconductor layer 420 (such as a p-type semiconductor layer), while the thickness H2 of the well layer 114 gradually increases toward the side close to the second type doped semiconductor layer 420 (such as a p-type semiconductor layer). In other words, the well layer 114 and the barrier layer 112 in the well-barrier pair 110 are disposed with their thicknesses being graded. Moreover, the gradation in thickness appears in at least three well-barrier pairs 110, such that the stress difference between the well layer 114 and the barrier layer 112 is reduced, and further, the V-shaped defects caused by dislocation is reduced. Accordingly, the reduction of the defects of the multiple quantum well structure 200 suppresses leakage current. Then, the recombination of the electrons and holes is enhanced, so as to enhance the whole light emission efficiency of the light emitting device 400. In addition, in the present embodiment, the light emitting device 400 further includes a superlattice layer 440 disposed between the first type doped semiconductor layer 410 (such as an n-type semiconductor layer) and the light emitting layer 430. The superlattice layer 440 is a superlattice structure formed by alternately disposing an AlInGaN layer and a GaN layer, which also conduces to a reduction in density of the dislocation defects caused by the release of stress.

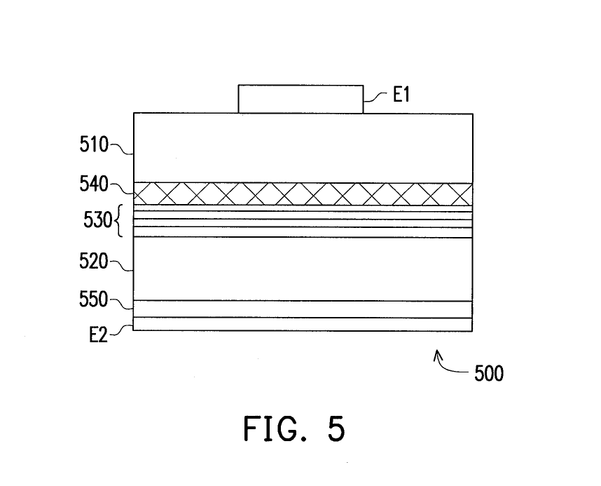

FIG. 5 is a schematic view of a light emitting device according to another embodiment of the invention. The light emitting device 500 of the present embodiment includes a first type doping semiconductor 510 (such as an n-type semiconductor layer), a light emitting layer 530, a second type doped semiconductor layer 520 (such as a p-type semiconductor layer), a first electrode E1 and a second electrode E2. It is known from FIG. 5 that the light emitting device 500 is a vertical-type light emitting device. Thus the first electrode E1 is disposed at another side of the first type doped semiconductor layer 510 (such as an n-type semiconductor layer), and the first type doped semiconductor layer 510 (such as an n-type semiconductor layer) is located between the light emitting layer 530 and the first electrode E1. In the present embodiment, the light emitting device 500 includes a conductive substrate 550 disposed between the second type doped semiconductor layer 520 (such as a p-type semiconductor layer) and the second electrode E2. It should be noted that the light emitting layer 530 also employs the above-described implementation pattern for the light emitting layer 430, and that is, the light emitting layer 530 also employs the multiple quantum well structures 100, 200 and 300 as described in the embodiments of FIG. 1A to FIG. 3A, and the well-barrier thickness ratio (H2/H1) gradually increases from the first type doped semiconductor layer 510 to the second type doped semiconductor layer 520. Therefore, the effects of the light emitting device 500 of the present embodiment may be derived by referring to the above descriptions and will not be repeated herein. In addition, in the present embodiment, the light emitting device 500 also further includes a superlattice layer 540 disposed between the first type doped semiconductor layer 510 (such as an n-type semiconductor layer) and the light emitting layer 530. The effects of the superlattice layer 540 may be derived by referring to the above descriptions.

In summary, in the multiple quantum well structure according to an embodiment of the invention, the well-barrier thickness ratios of a part of the well-barrier pairs gradually increase along the arrangement direction. Accordingly, the stress caused by lattice mismatch between the barrier layer and the well layer is effectively reduced, so as to reduce the chance of the V-shaped defects being formed in the multiple quantum well structure, and further to effectively enhance the quality of the multiple quantum well structure. In the multiple quantum well structure according to another embodiment of the invention, the well-barrier thickness ratios of at least a part of the well-barrier pairs gradually increase along the arrangement direction. The thicknesses of the barrier layers and the well layers in the well-barrier pairs are graded, so as to effectively reduce the stress caused by lattice mismatch between the barrier layer and the well layer. Accordingly, the chance of the V-shaped defects being formed in the multiple quantum well structure is reduced, and further, the quality of the multiple quantum well structure is effectively enhanced. In the multiple quantum well structure according to still another embodiment of the invention, the total well-barrier thickness ratios of at least a part of the plurality of sets of well-barrier pairs gradually increase along the arrangement direction, so as to effectively reduce the stress caused by lattice mismatch between the barrier layer and the well layer. Accordingly, the chance of the V-shaped defects being formed in the multiple quantum well structure is reduced, and further, the quality of the multiple quantum well structure is effectively enhanced.

Although the invention has been described with reference to the above embodiments, it is apparent to one of the ordinary skill in the art that modifications to the described embodiments may be made without departing from the spirit of the invention. Accordingly, the scope of the invention will be defined by the attached claims not by the above detailed descriptions.

What is claimed is:

1. A multiple quantum well structure regarded as a light emitting layer comprising:
a plurality of well-barrier pairs arranged along a direction, each of the well-barrier pairs comprising:
a barrier layer; and
a well layer adjacent to the barrier layer,
wherein the barrier layers and the well layers of the well-barrier pairs are disposed alternately, a ratio of a thickness of the well layer in the direction to a thickness of the barrier layer in the direction in each of the well-barrier pairs is a well-barrier thickness ratio, and the well-barrier thickness ratios of a part of the well-barrier pairs gradually increase along the direction.

2. The multiple quantum well structure as claimed in claim 1, wherein an n-type semiconductor layer and a p-type semiconductor layer are respectively disposed at two opposite sides of the well-barrier pairs, and the well-barrier thickness ratios of a part of the well-barrier pairs gradually increase from a side close to the n-type semiconductor layer to a side close to the p-type semiconductor layer.

3. The multiple quantum well structure as claimed in claim 2, wherein the thicknesses of the barrier layers of a part of the well-barrier pairs in the direction gradually decrease from the side close to the n-type semiconductor layer to the side close to the p-type semiconductor layer.

4. The multiple quantum well structure as claimed in claim 2, wherein the thicknesses of the well layers of a part of the well-barrier pairs in the direction gradually increase from the side close to the n-type semiconductor layer to the side close to the p-type semiconductor layer.

5. The multiple quantum well structure as claimed in claim 1, wherein the barrier layers are gallium nitride (GaN) layers and the well layers are indium gallium nitride (InGaN) layers.

6. The multiple quantum well structure as claimed in claim 1, wherein the well-barrier thickness ratio of each of the well-barrier pairs is greater than or equal to 0.25 and is smaller than or equal to 2.

7. The multiple quantum well structure as claimed in claim 1, wherein the thicknesses of the barrier layers of a part of the well-barrier pairs in the direction gradually decrease along the direction.

8. The multiple quantum well structure as claimed in claim 1, wherein the thicknesses of the well layers of a part of the well-barrier pairs in the direction gradually increase along the direction.

9. The multiple quantum well structure as claimed in claim 1, wherein the well-barrier thickness ratios of at least three well-barrier pairs among the well-barrier pairs gradually increase along the direction.

10. A multiple quantum well structure regarded as a light emitting layer comprising:
a plurality of well-barrier pairs arranged along a direction, each of the well-barrier pairs comprising:
a barrier layer; and
a well layer adjacent to the barrier layer,
wherein the barrier layers and the well layers of the well-barrier pairs are disposed alternately, a ratio of a thickness of the well layer in the direction to a thickness of the bather layer in the direction in each of the well-barrier pairs is a well-barrier thickness ratio, the well-barrier thickness ratios of at least a part of the well-barrier pairs gradually increase along the direction, the thicknesses of the barrier layers of the well-barrier pairs in the direction gradually decrease along the direction, and the thicknesses of the well layers of the well-barrier pairs in the direction gradually increase along the direction.

11. The multiple quantum well structure as claimed in claim 10, wherein an n-type semiconductor layer and a p-type semiconductor layer are respectively disposed at two opposite sides of the well-barrier pairs, the well-barrier thickness ratios of at least a part of the well-barrier pairs gradually increase from a side close to the n-type semiconductor layer to a side close to the p-type semiconductor layer, the thicknesses of the barrier layers of the well-barrier pairs in the direction gradually decrease from the side close to the n-type semiconductor layer to the side close to the p-type semiconductor layer, and the thicknesses of the well layers of the well-barrier pairs in the direction gradually increase from the side close to the n-type semiconductor layer to the side close to the p-type semiconductor layer.

12. The multiple quantum well structure as claimed in claim 10, wherein the barrier layers are GaN layers and the well layers are InGaN layers.

13. The multiple quantum well structure as claimed in claim 10, wherein the well-barrier thickness ratio of each of the well-barrier pairs is greater than or equal to 0.25 and is smaller than or equal to 2.

14. The multiple quantum well structure as claimed in claim 10, wherein the well-barrier thickness ratios of at least three well-barrier pairs among the well-barrier pairs gradually increase along the direction.

15. A multiple quantum well structure regarded as a light emitting layer comprising:
a plurality of sets of well-barrier pairs arranged along a direction, each set of the well-barrier pairs comprising a plurality of adjacent stacked well-barrier pairs, each of the well-barrier pairs comprising:
a barrier layer; and
a well layer adjacent to the barrier layer,
wherein the barrier layers and the well layers of the well-barrier pairs of the plurality of sets of well-barrier pairs are disposed alternately, a ratio of a total thickness of the well layers of the well-barrier pairs in the direction to a total thickness of the barrier layers of the well-barrier pairs in the direction in each set of the well-barrier pairs is a total well-barrier thickness ratio, and the total well-barrier thickness ratios of at least a part of the plurality of sets of well-barrier pairs gradually increase along the direction.

16. The multiple quantum well structure as claimed in claim 15, wherein an n-type semiconductor layer and a p-type semiconductor layer are respectively disposed at two opposite sides of the well-barrier pairs, and the total well-barrier thickness ratios of at least a part of the plurality of sets of well-barrier pairs gradually increase from a side close to the n-type semiconductor layer to a side close to the p-type semiconductor layer.

17. The multiple quantum well structure as claimed in claim 16, wherein the thicknesses of the barrier layers of at least a part of the well-barrier pairs in the direction gradually decrease from the side close to the n-type semiconductor layer to the side close to the p-type semiconductor layer.

18. The multiple quantum well structure as claimed in claim 16, wherein the thicknesses of the well layers of at least a part of the well-barrier pairs in the direction gradually increase from the side close to the n-type semiconductor layer to the side close to the p-type semiconductor layer.

19. The multiple quantum well structure as claimed in claim 15, wherein the barrier layers are GaN layers and the well layers are InGaN layers.

20. The multiple quantum well structure as claimed in claim 15, wherein the well-barrier thickness ratio of each of the well-barrier pairs is greater than or equal to 0.25 and is smaller than or equal to 2.

21. The multiple quantum well structure as claimed in claim 15, wherein the thicknesses of the barrier layers of at least a part of the well-barrier pairs in the direction gradually decrease along the direction, and the thicknesses of the well layers of at least a part of the well-barrier pairs in the direction gradually increase along the direction.

22. The multiple quantum well structure as claimed in claim 15, wherein a ratio of a thickness of the well layer in the direction to a thickness of the barrier layer in the direction in each of the well-barrier pairs is a well-barrier thickness ratio, and the well-barrier thickness ratios of at least three well-barrier pairs among the well-barrier pairs gradually increase along the direction.
